(19) United States
(12) Patent Application Publication
(10) Pub. No.: US 2026/0164146 A1
(43) Pub. Date: Jun. 11, 2026

(54) PHOTOELECTRIC CONVERSION DEVICE AND APPARATUS

(71) Applicant: CANON KABUSHIKI KAISHA, Tokyo (JP)

(72) Inventors: MAKIKO SAITO, Tokyo (JP); SATOSHI KATO, Kanagawa (JP)

(21) Appl. No.: 19/180,309

(22) Filed: Apr. 16, 2025

(30) Foreign Application Priority Data
Apr. 26, 2024 (JP) 2024-072927

(51) Int. Cl. H04N 25/77; H03M 1/12; H03M 1/18; H04N 25/571; H04N 25/701; H04N 25/78

(52) U.S. Cl. CPC H04N 25/77; H03M 1/121; H03M 1/186; H04N 25/575; H04N 25/701; H04N 25/78

(57) ABSTRACT

A photoelectric convertor including pixels, ramp signal lines and first and second A/D conversion circuits that are adjacent to each other is provided. Each of the first and second A/D conversion circuits includes a selector selecting a ramp signal line, a comparator comparing a ramp signal with a pixel signal and a supply line connecting the selector and the comparator. The supply line includes a first portion extending from the comparator and a second portion connecting the first portion and the selector. A region in which the supply line is arranged includes, between the first portion of the first A/D conversion circuit and the second portion of the second A/D conversion circuit, a region where the second portion of the first A/D conversion circuit or the first portion of the second A/D conversion circuit is arranged.

### BACKGROUND OF THE INVENTION

### Field of the Invention

The present disclosure relates to a photoelectric conversion device and an apparatus.

### Description of the Related Art

As the number of pixels and the frame rate are increasing in television standards, even a photoelectric conversion device that senses a television image needs to achieve a larger number of pixels and a higher frame rate for a recordable image. To meet this demand, the analog-to-digital converter (ADC) of the photoelectric conversion device needs to speed up. In addition to a large number of pixels and a high frame rate, a wide dynamic range is also an important element for image expression. Japanese Patent Laid-Open No. 2021-153291 discloses an image sensing apparatus configured to supply ramp signals of different slopes to an ADC in accordance with the magnitude of a signal obtained in a pixel so that the dynamic range can be improved without increasing the time taken for A/D conversion.

### SUMMARY OF THE INVENTION

To increase the frame rate, it is conceivable to provide a plurality of ADCs for each pixel column and perform signal processing simultaneously for signals output from pixels of a plurality of rows. When a plurality of ADCs are provided for each pixel column, an unintentional coupling capacitance may be generated between wiring patterns for inputting a signal to the ADC, between density arranged ADCs. In a case where ramp signals of different slopes are supplied to nearby ADCs, if the ramp signals of different slopes affect each other via the coupling capacitance, the slope of the ramp signal changes and the A/D conversion gain also changes. As a result, the quality of an obtained image may degrade.

Some embodiments of the present disclosure provide a technique advantageous for improving the characteristics of a photoelectric conversion device.

According to some embodiments, a photoelectric conversion device comprising: a pixel circuit in which a plurality of pixels are arranged to constitute a plurality of rows and a plurality of columns; a plurality of ramp signal lines to which ramp signals of different slopes are supplied; and an A/D converter in which a plurality of A/D conversion circuits including a first A/D conversion circuit and a second A/D conversion circuit that are adjacent to each other are arranged in correspondence with one column, wherein each of the plurality of A/D conversion circuits includes a selection circuit configured to select a ramp signal line from the plurality of ramp signal lines to select a ramp signal used for A/D conversion, a comparison circuit configured to compare a ramp signal selected by the selection circuit with a pixel signal from the pixel, and a supply line configured to supply the ramp signal from the selection circuit to the comparison circuit, the supply line includes a first portion extending from the comparison circuit, and a second portion connecting the first portion and the selection circuit, and a wiring region in which the supply line is arranged includes, between the first portion of the first A/D conversion circuit and the second portion of the second A/D conversion circuit, a region where one of the second portion of the first A/D conversion circuit and the first portion of the second A/D conversion circuit is arranged, is provided.

According to some embodiments, a photoelectric conversion device comprising: a pixel circuit in which a plurality of pixels are arranged to constitute a plurality of rows and a plurality of columns; a plurality of ramp signal lines to which ramp signals of different slopes are supplied; and an A/D converter in which a plurality of A/D conversion circuits including a first A/D conversion circuit and a second A/D conversion circuit that are adjacent to each other are arranged in correspondence with one column, wherein each of the plurality of A/D conversion circuits includes a selection circuit configured to select a ramp signal line from the plurality of ramp signal lines to select a ramp signal used for A/D conversion, a comparison circuit configured to compare a ramp signal selected by the selection circuit with a pixel signal from the pixel, and a supply line configured to supply the ramp signal from the selection circuit to the comparison circuit, the supply line includes a first portion extending from the comparison circuit, and a second portion connecting the first portion and the selection circuit, a wiring region in which the supply line is arranged includes a region where the first portion and second portion of the first A/D conversion circuit and the first portion and second portion of the second A/D conversion circuit are arranged parallel on an identical wiring layer, and the photoelectric conversion device has at least one of a driving mode in which, while the selection circuit selects, from the plurality of ramp signal lines, a ramp signal line for supplying a first ramp signal and the first ramp signal is supplied to the comparison circuit in the first A/D conversion circuit, the first ramp signal is supplied to the comparison circuit in the second A/D conversion circuit, and a driving mode in which a predetermined voltage is supplied to the comparison circuit, is provided.

Further features of the present invention will become apparent from the following description of exemplary embodiments (with reference to the attached drawings).

### BRIEF DESCRIPTION OF THE DRAWINGS

FIG. 1 is a block diagram showing an example of the arrangement of a photoelectric conversion device according to an embodiment;

FIG. 2 is a circuit diagram showing an example of the arrangement of the A/D conversion circuit of the photoelectric conversion device in FIG. 1;

FIG. 3 is a circuit diagram showing an example of the arrangement of the A/D conversion circuit of the photoelectric conversion device in FIG. 1;

FIGS. 4A and 4B are a circuit diagram and a timing chart respectively showing an example of the operation of the A/D conversion circuit of the photoelectric conversion device in FIG. 1;

FIG. 5 is a view showing an example of the layout of the A/D conversion circuit of the photoelectric conversion device in FIG. 1;

FIGS. 6A and 6B are views showing an example of the layout of wiring patterns for supplying a ramp signal in the A/D conversion circuit of the photoelectric conversion device in FIG. 1;

FIG. 7 is a circuit diagram showing an example of the arrangement of the A/D conversion circuit of the photoelectric conversion device in FIG. 1;

FIG. 8 is a timing chart showing an example of the operation of the A/D conversion circuit of the photoelectric conversion device in FIG. 1;

FIG. 9 is a circuit diagram showing an example of the arrangement of the A/D conversion circuit of the photoelectric conversion device in FIG. 1; and

FIG. 10 is a view showing an example of the arrangement of an apparatus incorporating the photoelectric conversion device in FIG. 1.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made to an invention that requires all such features, and multiple such features may be combined as appropriate. Furthermore, in the attached drawings, the same reference numerals are given to the same or similar configurations, and redundant description thereof is omitted.

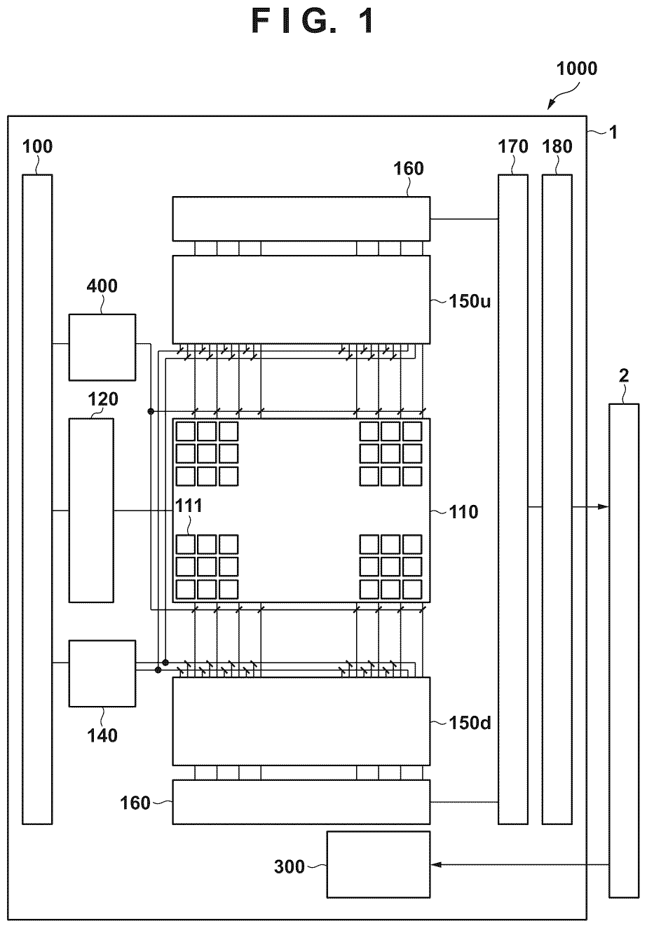

A photoelectric conversion device according to an embodiment of the present disclosure will be explained with reference to FIGS. 1 to 9. FIG. 1 is a block diagram showing an example of the arrangement of an image sensing apparatus 1000 including a photoelectric conversion device 1 according to the embodiment. The image sensing apparatus 1000 includes the photoelectric conversion device 1 including a parallel A/D converter, and an image processing LSI 2. The photoelectric conversion device 1 can also be called a CMOS image sensor or the like.

The image processing LSI 2 performs various processes on image data output from the photoelectric conversion device 1. The processes performed by the image processing LSI 2 are, for example, white balance processing, gamma processing, high dynamic range composition processing, and processing of correcting the ratio of two pixel signals of different gains. Image data output from the photoelectric conversion device 1 and image data processed by the image processing LSI 2 are recorded on a recording medium such as a memory. The recording medium may be incorporated in the image processing LSI 2 or arranged separately from the image sensing apparatus 1000. The image processing LSI 2 may incorporate the CPU of a computer, and the CPU may perform communication (for example, serial communication) with the photoelectric conversion device 1 or the like based on a computer program stored in a memory to control the overall image sensing apparatus 1000.

The photoelectric conversion device 1 includes a pixel circuit 110, a vertical scanning circuit 120, a ramp circuit 140, an A/D converter 150, a horizontal transfer circuit 160, a signal processing circuit 170, an external output circuit 180, a controller circuit 300, and the like. The photoelectric conversion device 1 may include, for example, an amplifier between the pixel circuit 110 and the A/D converter 150 to amplify an analog signal (pixel signal) from the pixel circuit 110.

The controller circuit 300 is an interface with the image processing LSI 2, and receives a control signal from the CPU of the image processing LSI 2 to the photoelectric conversion device 1 by using serial communication or the like. The controller circuit 300 controls each constituent element in the photoelectric conversion device 1.

In the pixel circuit 110, a plurality of pixels 111 are arranged to constitute a plurality of rows and a plurality of columns. Each pixel 111 includes a photoelectric conversion element (for example, a photodiode) that photoelectrically converts incident light in accordance with its quantity and outputs a voltage signal. In the pixel 111, a color filter, a microlens, and the like can be arranged on an incident surface through which light enters the photoelectric conversion element. For example, any of color filters of three colors that transmit red, green, and blue may be periodically arranged in accordance with each of the photoelectric conversion elements arranged in the pixels 111. The color filters may have a Bayer array for the entire pixel circuit 110, but are not limited to this.

A timing control circuit 100 supplies an operation clock CLK or a timing signal to each constituent element of the photoelectric conversion device 1. The timing control circuit 100 controls the operation of each constituent element by the operation clock CLK or the timing signal.

The vertical scanning circuit 120 performs timing control for sequentially reading out, for respective rows in one frame, the output signals of the pixels 111 two-dimensionally arranged in the pixel circuit 110. For example, signals are read out in one frame sequentially from the pixels 111 on respective rows from an upper row toward a lower row shown in FIG. 1 in the pixel circuit 110.

A constant-voltage circuit 400 can supply a predetermined voltage to each signal output line. Instead of the constant-voltage circuit 400, a clipping circuit may be used to clip a signal at a constant voltage.

The ramp circuit 140 is a signal generator that generates a voltage signal of a ramp shape (ramp signal) whose voltage changes with a constant slope over time. As will be described later, the ramp circuit 140 can generate a plurality of ramp signals having different slopes.

The A/D converter 150 includes a comparison circuit that compares a pixel signal read out from the pixel circuit 110 with a ramp signal supplied from the ramp circuit 140. The A/D converter 150 also includes a counter/latch circuit that counts the time until the voltage level of the pixel signal and that of the ramp signal coincide with each other as a result of comparison by the comparison circuit, and latches the count value. A detailed arrangement of the A/D conversion circuit for each pixel column in the A/D converter 150 will be described later.

In the embodiment, the A/D converter 150 includes an A/D converter 150u and an A/D converter 150d. As shown in FIG. 1, the A/D converters 150u and 150d are provided respectively on the upper and lower sides of the pixel circuit 110. In other words, the pixel circuit 110 is arranged between the A/D converters 150u and 150d. For example, pixel signals output from the pixels 111 arranged on odd rows of the pixel circuit 110 may be converted into time count values by the A/D converter 150u arranged on the upper side of the pixel circuit 110, and the time count values may be read out. Also, pixel signals output from the pixels 111 arranged on even rows of the pixel circuit 110 may be converted into time count values by the A/D converter 150d arranged on the lower side of the pixel circuit 110, and the time count values may be read out.

The count values of respective columns for each row that are latched by the counter/latch circuit of the A/D converter 150 are sequentially read out as A/D-converted image data by the horizontal transfer circuit 160 from, for example, a column corresponding to the right end of the pixel circuit 110. The image data output from the horizontal transfer circuit 160 are input to the signal processing circuit 170. The signal processing circuit 170 is a circuit that digitally performs signal processing. For example, the signal processing circuit 170 may add a predetermined offset value by digital processing, or perform shift calculation or multiplication. That is, the signal processing circuit 170 can perform digital gain calculation.

The image data output from the signal processing circuit 170 is supplied to the external output circuit 180. The external output circuit 180 has a serializer function, and converts a multi-bit parallel signal input from the signal processing circuit 170 into a serial signal. The external output circuit 180 converts the serial signal into a signal of, for example, the Low Voltage Differential Signaling (LVDS) standard, and outputs the converted signal as image data to an external device (for example, the image processing LSI 2).

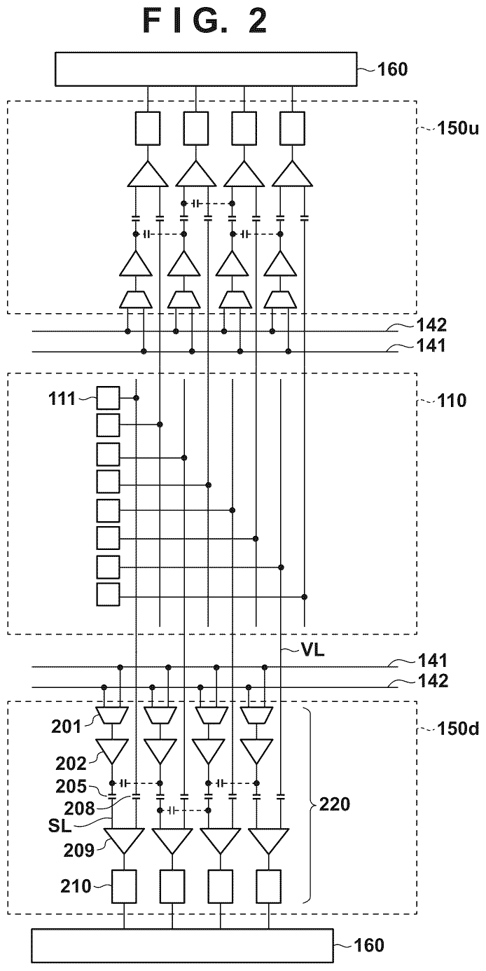

Next, the arrangement and operation of an A/D converter 150 according to the first embodiment of the present disclosure will be explained. FIG. 2 is a circuit block diagram showing a detailed arrangement of an A/D conversion circuit 220 corresponding to one pixel column of a pixel circuit 110 in the A/D converter 150. As shown in FIG. 2, two A/D converters 150u and 150d are so provided as to sandwich the pixel circuit 110. A plurality of A/D conversion circuits 220 are arranged in the A/D converters 150u and 150d in correspondence with one column. Although eight pixels 111 of eight rows arranged on one column are shown for descriptive convenience in the arrangement shown in FIG. 2, the number of rows on which the pixels 111 are arranged is not limited to this.

Each of the A/D conversion circuits 220 includes a selection circuit 201, a buffer circuit 202, a comparison circuit 209, and a counter/latch circuit 210. In a photoelectric conversion device 1, a plurality of ramp signal lines (two ramp signal lines 141 and 142 in the arrangement shown in FIG. 2) to which ramp signals of different slopes are supplied from a ramp circuit 140 are arranged. The selection circuit 201 selects the ramp signal line 141 or 142 from the ramp signal lines 141 and 142 so as to select a ramp signal used for A/D conversion. The embodiment describes an arrangement in which two types of ramp signals are supplied from the ramp circuit 140 via the two ramp signal lines 141 and 142. However, the arrangement is not limited to this, and it is also possible to arrange three or more ramp signal lines and select a ramp signal line by the selection circuit 201 so as to select a ramp signal used for A/D conversion from three or more types of ramp signals. The buffer circuit 202 corrects the signal voltage of the ramp signal supplied from the selection circuit 201, and outputs the ramp signal to the subsequent comparison circuit 209. The buffer circuit 202 can be, for example, a source follower circuit. The comparison circuit 209 compares a ramp signal selected by the selection circuit 201 with a pixel signal from the pixel 111. The counter/latch circuit 210 stores a time count value as an A/D conversion result, and outputs it to a subsequent horizontal transfer circuit 160. The A/D conversion circuit 220 includes supply lines SL for supplying a ramp signal from the selection circuit 201 to the comparison circuit 209. Each supply line SL connects the output terminal of the selection circuit 201 and one input terminal of the comparison circuit 209 via the buffer circuit 202 and an input capacitance 205. In the arrangement shown in FIG. 2, four A/D conversion circuits 220 are arranged on each side of the pixel circuit 110, that is, a total of eight A/D conversion circuits 220 are arranged on two sides of the pixel circuit 110 in correspondence with one column. However, the number of A/D conversion circuits 220 per column is not limited to this, and may be two or more and seven or less, or eight or more.

To transfer pixel signals from the pixel circuit 110 to the A/D converters 150u and 150d, a plurality of signal output lines VL are provided in correspondence with the respective A/D conversion circuits 220 provided for respective columns on which the pixels 111 of the pixel circuit 110 are arranged. Each signal output line VL is connected to the comparison circuit 209 via an input capacitance 208. In the arrangement shown in FIG. 2, pixel signals output from the pixels 111 arranged on odd rows of the pixel circuit 110 are read out to the A/D conversion circuits 220 of the A/D converter 150d via the signal output lines VL. Also, pixel signals output from the pixels 111 arranged on even rows of the pixel circuit 110 are read out to the A/D conversion circuits 220 of the A/D converter 150u via the signal output lines VL. Amplifier circuits may be provided between the signal output lines VL and the A/D converters 150u and 150d so that signal voltages output from the pixels 111 are input to the comparison circuits 209 of the A/D conversion circuits 220 after they are amplified. The remaining arrangement of the A/D converter 150 can be common between the A/D converters 150u and 150d.

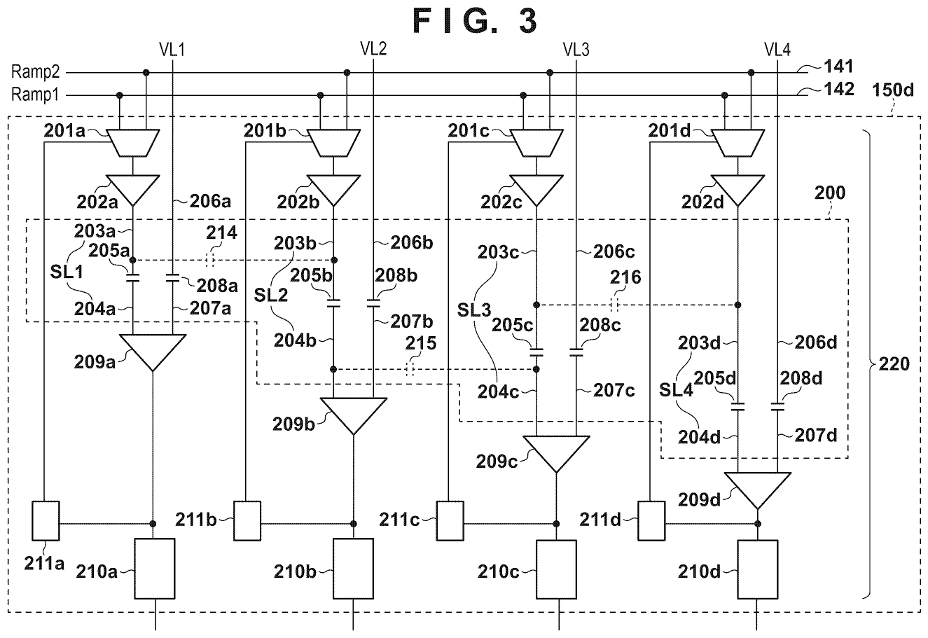

FIG. 3 is a circuit block diagram showing the A/D converter 150 in more detail. FIG. 3 shows the A/D converter 150d, but the A/D converter 150u can also have a similar arrangement.

Signal output lines VL1 to VL4 are signal output lines corresponding to one pixel column arranged in the pixel circuit 110. Pixel signals are input to the respective signal output lines from the pixels 111 provided on the same pixel column of the pixel circuit 110. Each signal output line VL includes a portion 206 connected to the pixel 111, a portion 207 connected to the comparison circuit 209, and the input capacitance 208. In FIG. 3, potions 206a to 206d, potions 207a to 207d, and input capacitances 208a to 208d are shown in accordance with the signal output lines VL1 to VL4. When a specific signal output line out of the signal output lines VL is indicated, a suffix will be attached to a reference sign, like the signal output line VL“1”. Similarly, when a specific portion of the portion 206 is indicated, a suffix will be attached to a reference sign, like the portion 206“a”. This also applies to the remaining constituent elements.

As described above, the selection circuit 201 selects either the ramp signal line 141 or 142 so as to select a ramp signal Ramp1 supplied from the ramp circuit 140 to the ramp signal line 141 and a ramp signal Ramp2 supplied from the ramp circuit 140 to the ramp signal line 142. The selection circuit 201 outputs the ramp signal Ramp1 or Ramp2 to the comparison circuit 209 for each selection circuit 201.

The supply line SL for supplying the ramp signal Ramp1 or Ramp2 from the selection circuit 201 to the comparison circuit 209 includes, at the input capacitance 205 serving as a boundary, a portion 204 extending from the comparison circuit 209, and a portion 203 connecting the portion 204 and the selection circuit 201. In other words, the portion 203 is a portion extending from the selection circuit 201 to the input capacitance 205 via the buffer circuit 202. Also, in other words, the buffer circuit 202 is arranged at the portion 203 out of the supply line SL.

One of two input terminals of the comparison circuit 209 receives the ramp signal Ramp1 or Ramp2 that passes through the supply line SL including the input capacitance 205 and is selected by the selection circuit 201 via the buffer circuit 202. The other of two input terminals of the comparison circuit 209 receives, from the pixel 111 via the input capacitance, a signal voltage (pixel signal) that passes through the signal output line VL. The comparison circuit 209 compares the input pixel signal and ramp signal, and outputs a signal level corresponding to the comparison result. As an example, when the voltage level of the ramp signal Ramp1 or Ramp2 is higher than that of the pixel signal, H level is output, and when the voltage level of the ramp signal Ramp1 or Ramp2 is lower than that of the pixel signal, L level is output. In this arrangement, as the signal voltage of the ramp signal Ramp1 or Ramp2 is monotonously increased over time, the time until the output of the comparison circuit 209 is inverted from H level to L level is counted. The time count value can be used as the A/D conversion result of the pixel signal.

Instead of the ramp signals Ramp1 and Ramp2, a predetermined voltage is input to the comparison circuit 209 and compared with the pixel signal. Hence, the comparison circuit 209 can be used as a level determination circuit that determines whether the signal level of the pixel signal is higher or lower than the predetermined voltage. Details of the operation of the comparison circuit 209 used as the level determination circuit will be described later. As shown in FIG. 3, the A/D conversion circuit 220 may include a determination holding circuit 211 to hold the determination result of the comparison circuit 209 when the comparison circuit 209 is used as the level determination circuit. The comparison circuit 209 may be configured to generate a determination signal in accordance with the held determination result and feed it back to the selection circuit 201. In accordance with the fed-back determination signal, the selection circuit 201 can select the ramp signal Ramp1 or Ramp2.

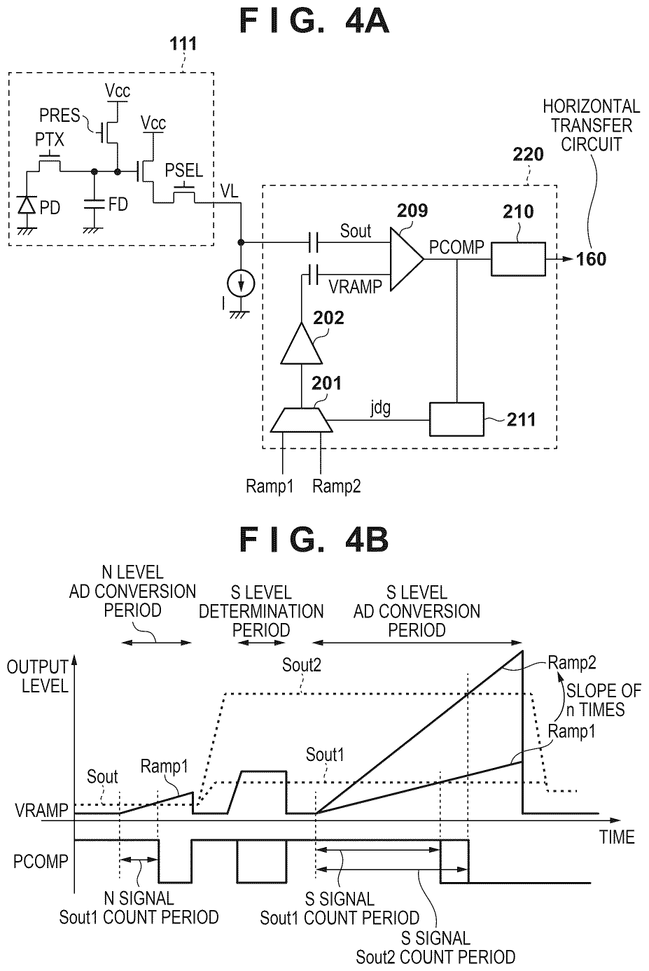

Next, the operation timing of the A/D conversion circuit 220 regarding A/D conversion according to the embodiment will be explained with reference to FIGS. 4A and 4B. As shown in FIG. 4A, the comparison circuit 209 compares an input voltage Sout and an input voltage VRAMP, and outputs a comparison signal PCOMP as a comparison result. In the embodiment, the input voltage Sout is a voltage corresponding to a pixel signal input to the comparison circuit 209 from the pixel 111 via the signal output line VL. The input voltage VRAMP is a voltage corresponding to the ramp signal Ramp1 or Ramp2 that is selected by the selection circuit 201 and input to the comparison circuit 209 via the buffer circuit 202.

FIG. 4B shows the operation timing of the A/D conversion circuit 220. In the embodiment, when A/D-converting the signal of the pixel 111, a noise signal (to be also referred to as a N signal hereinafter) is first read out from the pixel 111 and A/D-converted. Then, a signal photoelectrically converted by the photoelectric conversion element and a noise-containing S signal are read out from the pixel 111 and A/D-converted. A signal processing circuit 170 performs subtraction processing on these two digital signals to subtract the N signal from the S signal, canceling the noise component and improving the S/N ratio.

In a period in which the N signal is A/D-converted, a reset level is read out as the N signal from the pixel 111 of the pixel circuit 110 to the signal output line VL. All the selection circuits 201 arranged in the A/D converter 150 select, from the ramp signals Ramp1 and Ramp2 supplied from the ramp circuit 140, the ramp signal line 142 to which the ramp signal Ramp1 gentler in slope than the ramp signal Ramp2 is supplied. A voltage corresponding to the ramp signal Ramp1 is supplied as the input voltage VRAMP to the comparison circuit 209 via the buffer circuit 202. At the same time as the start of supplying the input voltage VRAMP (ramp signal Ramp1), time count by the counter of the counter/latch circuit 210 starts. The comparison circuit 209 compares the input voltage Sout corresponding to the N signal with the input voltage VRAMP corresponding to the ramp signal Ramp1, and while the input voltage Sout is higher than the ramp signal Ramp1, outputs H level as the comparison signal PCOMP. When the voltage level of the ramp signal Ramp1 rises over time and exceeds the input voltage Sout, the comparison signal PCOMP is inverted to L level. In response to the inversion of the comparison signal PCOMP from H level to L level, the counter/latch circuit 210 stores the time count value obtained by the counter as the digital value of the N signal.

Upon completion of A/D conversion of the N signal, the operation shifts to a level determination period in which the comparison circuit 209 is used as the level determination circuit. In the level determination period, the signal level of the S signal accumulated in the pixel 111 of the pixel circuit 110 is determined. First, the S signal accumulated in the pixel 111 arranged in the pixel circuit 110 is read out to the signal output line VL. Meanwhile, the ramp circuit 140 supplies a fixed voltage Vth serving as the determination threshold of the signal level to at least either of the ramp signal lines 141 and 142. The selection circuit 201 selects the ramp signal line 141 or 142 to which the fixed voltage Vth is supplied, and supplies the fixed voltage Vth as the input voltage VRAMP to the comparison circuit 209. The comparison circuit 209 compares the input voltage Sout corresponding to the S signal with the fixed voltage Vth. If the input voltage Sout is higher than the fixed voltage Vth, the comparison circuit 209 outputs H level, and if it is lower, outputs L level. For example, an input voltage Sout1 lower than the fixed voltage Vth is input as the S signal from the pixel 111 in which the quantity of incident light from an object is small, and the comparison circuit 209 outputs L level as the comparison signal PCOMP. An input voltage Sout2 higher than the fixed voltage Vth is input from the pixel 111 in which the quantity of incident light is large, and the comparison circuit 209 outputs H level as the comparison signal PCOMP. When the input voltage Sout and the input voltage VRAMP stabilize, the determination holding circuit 211 holds the level of the comparison signal PCOMP as a determination signal jdg.

Then, in a period in which the S signal is A/D-converted, the selection circuit 201 selects, based on the determination signal jdg from the corresponding determination holding circuit 211, either of the ramp signals Ramp1 and Ramp2 supplied from the ramp circuit 140. If the determination signal jdg is at L level, the selection circuit 201 selects the ramp signal Ramp1 having a gentle slope as the input voltage VRAMP, and if the determination signal jdg is at H level, selects the ramp signal Ramp2 having a steep slope as the input voltage VRAMP. At the same time as the start of supplying the input voltage VRAMP (ramp signal Ramp1 or Ramp2), time count by the counter of the counter/latch circuit 210 starts. The comparison circuit 209 compares the input voltage Sout corresponding to the S signal with the input voltage VRAMP corresponding to the ramp signal Ramp1 or Ramp2 selected by the selection circuit 201. While the input voltage Sout is higher than the input voltage VRAMP, the comparison circuit 209 outputs H level as the comparison signal PCOMP. When the voltage level of the input voltage VRAMP rises over time and exceeds the input voltage Sout, the comparison signal PCOMP is inverted to L level. In response to the inversion of the comparison signal PCOMP from H level to L level, the counter/latch circuit 210 stores the time count value obtained by the counter as the digital value of the S signal.

When the slope of the ramp signal Ramp2 is N times of the slope of the ramp signal Ramp1, the time until the ramp signal Ramp2 becomes equal to the input voltage Sout becomes 1/N times of the time until the ramp signal Ramp1 becomes equal to the input voltage Sout. In accordance with the level determination result, the input voltage Sout of low voltage level is A/D-converted using the ramp signal Ramp1 having a gentle slope as the input voltage VRAMP. In contrast, the input voltage Sout of high voltage level is A/D-converted using the ramp signal Ramp2 having a steep slope as the input voltage VRAMP. This can shorten the time taken for A/D conversion. For a pixel signal (input voltage Sout) of the same signal level, a time count value when the ramp signal Ramp2 having a steep slope is selected becomes 1/N times of a time count value when the ramp signal Ramp1 having a gentle slope is selected. A correction gain of N times is applied by bit shift or correction by a subsequent signal processing circuit on a pixel value A/D-converted using the ramp signal Ramp2 as the input voltage VRAMP. The resultant pixel value can be handled as a pixel signal of the same tone level as that of a pixel value A/D-converted using the ramp signal Ramp1.

As described above, according to the embodiment, a ramp signal to be used is selected in accordance with the level of a pixel signal input to the A/D conversion circuit 220. That is, the photoelectric conversion device 1 performs an operation capable of selecting different ramp signals for the comparison circuits 209 arranged in the respective A/D conversion circuits 220.

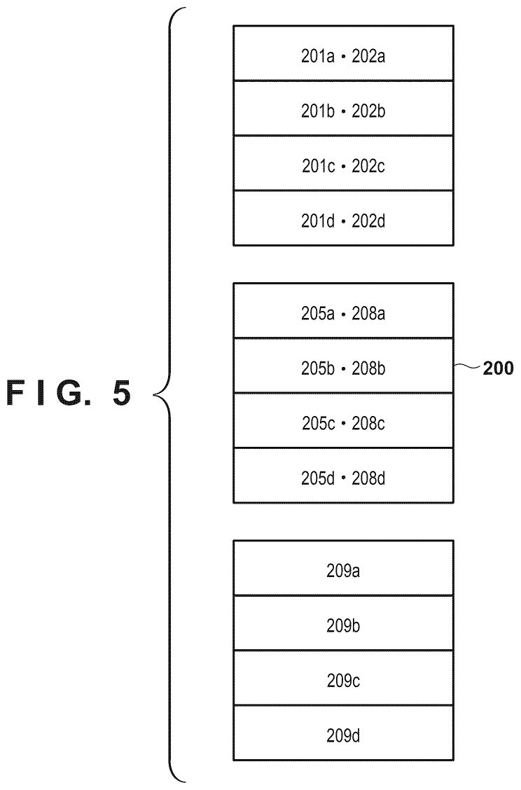

Next, the physical layout image of circuit blocks constituting the A/D converter 150 will be explained with reference to the conceptual diagram of FIG. 5. Of the circuit blocks constituting the A/D converter 150, circuit blocks of the same type are laid out so that they are arranged collectively in nearby regions. This is because it is suitable to form circuit elements arranged in circuit blocks of the same type in nearby regions in order to reduce characteristic variations in manufacturing generated between the circuit blocks of the same type. Here, of circuit blocks corresponding to the signal output lines VL1, VL2, VL3, and VL4, selection circuits 201a, 201b, 201c, and 201d, and buffer circuits 202a, 202b, 202c, and 202d are arranged in nearby regions, respectively. Also, comparison circuits 209a, 209b, 209c, and 209d are arranged in nearby regions. A wiring region 200 represents a region between the buffer circuits 202a, 202b, 202c, and 202d and the comparison circuits 209a, 209b, 209c, and 209d. In the wiring region 200, portions 203a, 203b, 203c, and 203d, portions 204a, 204b, 204c, and 204d, and input capacitances 205a, 205b, 205c, and 205d, which are part of the supply lines SL, are arranged. Also, in the wiring region 200, portions 206a, 206b, 206c, and 206d, portions 207a, 207b, 207c, and 207d, and input capacitances 208a, 208b, 208c, and 208d, which are part of the signal output lines VL1, VL2, VL3, and VL4, are arranged.

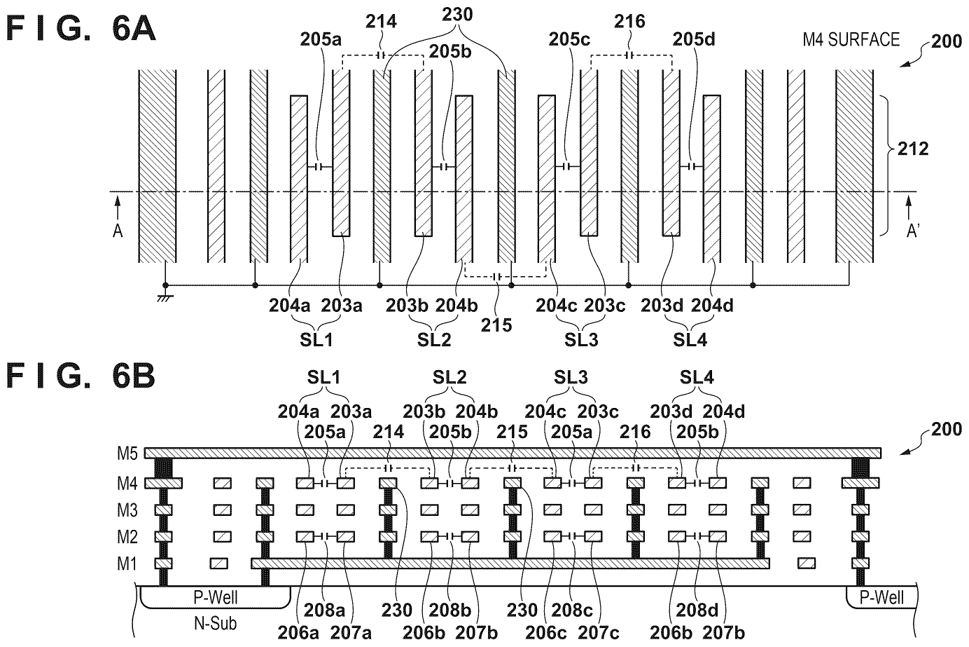

FIGS. 6A and 6B show a wiring layout corresponding to the wiring region 200 shown in FIG. 5. In other words, FIGS. 6A and 6B show a wiring layout focused on the portions 203 and 204 and input capacitance 205 of the supply line SL in FIG. 3. FIG. 6A shows the two-dimensional layout of a wiring layer on which the supply line SL is arranged. FIG. 6B is a sectional view taken along a line A-A′ in FIG. 6A. As shown in FIG. 6A, the wiring region 200 includes a region 212 where the portions 203 and 204 of the respective A/D conversion circuits 220 are arranged parallel on a wiring layer M4. At this time, for example, the portions 203a and 204a corresponding to one A/D conversion circuit 220 are arranged to face each other, thereby forming the input capacitance 205a between the portions 203a and 204a. The supply line SL of each A/D conversion circuit 220 can supply the ramp signals Ramp1 and Ramp2 from the selection circuit 201 to the comparison circuit 209 by capacitive coupling between the portions 203 and 204 in the region 212. In the arrangement shown in FIG. 6A, the portions 203 and 204 of the supply line SL are arranged on the wiring layer M4, and the input capacitance 205 is formed between the portions 203 and 204. However, the arrangement is not limited to this, and a capacitive element may be formed as the input capacitance on a wiring layer M1, M2, M3, or M5 different from the wiring layer M4 on which the portions 203 and 204 are arranged. In this case, the portion 203 and the capacitive element, and the portion 204 and the capacitive element can be connected by a conductive pattern through conductive vias or the like.

Here, attention is paid to the adjacent A/D conversion circuits 220. A shield line 230 for reducing a crosstalk generated by capacitive coupling is arranged between the portions 203a and 204a of the supply line SL1 of the A/D conversion circuit 220 including the comparison circuit 209a, and the portions 203b and 204b of the supply line SL2 of the A/D conversion circuit 220 including the comparison circuit 209b. The shield line 230 is also arranged between the portions 203b and 204b of the supply line SL2 of the A/D conversion circuit 220 including the comparison circuit 209b, and the portions 203c and 204c of the supply line SL3 of the A/D conversion circuit 220 including the comparison circuit 209c. Similarly, the shield line 230 is arranged between the portions 203c and 204c of the supply line SL3 of the A/D conversion circuit 220 including the comparison circuit 209c, and the portions 203d and 204d of the supply line SL4 of the A/D conversion circuit 220 including the comparison circuit 209d. As shown in FIG. 6A, the shield line 230 may be fixed to, for example, ground level. However, parasitic capacitances 214, 215, and 216 can be generated between the supply lines SL adjacent to each other via the shield line 230 owing to a gap of the shield line 230 or the like. As shown in FIG. 6B, the supply lines SL are arranged on the wiring layer M4. The shield lines 230 are also arranged on the same wiring layer M4, but the parasitic capacitances 214, 215, and 216 are generated via a dielectric between the wiring layers M4 and M5.

Assume that the parasitic capacitances 214 to 216 are generated between, for example, the portion 204a of the supply line SL1 connected to the comparison circuit 209a, and the portion 203b of the supply line SL2 connected to the selection circuit 201b that supplies a ramp signal to the adjacent comparison circuit 209b. In this case, the voltage level of the portion 204a of the supply line SL1 connected to the comparison circuit 209a complies with a ramp signal supplied from the selection circuit 201a via the portion 203a, but is also affected by a ramp signal supplied from the selection circuit 201b via the portion 203b of the supply line SL2. A case where a ramp signal input to the comparison circuit 209a and a ramp signal input to the comparison circuit 209b are different will be considered. For example, a case where the ramp signal Ramp1 is supplied from the selection circuit 201a to the comparison circuit 209a and the ramp signal Ramp2 is supplied from the selection circuit 201b to the comparison circuit 209b will be examined. In this case, a ramp signal input to the comparison circuit 209a via the portion 204a of the supply line SL1 changes from the slope of the ramp signal Ramp1, which should be originally input, to an intermediate slope between the slope of the ramp signal Ramp1 and that of the ramp signal Ramp2. If such an unintentional change of the slope of the ramp signal occurs in A/D conversion of some pixel signals in A/D-converting pixel signals, the A/D conversion gain becomes nonuniform within an image, degrading the quality of the obtained image.

In the embodiment, to suppress the unintentional change of the slope of the ramp signal, the portions 203 and 204 of the supply lines SL to which corresponding ramp signals are input are arranged symmetrically about the shield line 230 in the region 212 between the adjacent A/D conversion circuits 220. Attention is paid to the adjacent A/D conversion circuits 220 in the region 212 where the portions 203 and 204 of the supply lines SL are arranged parallel on the same wiring layer M4. For example, the portion 203a of the supply line SL1 of the A/D conversion circuit 220 including the comparison circuit 209a is arranged between the portion 204a of the supply line SL1 of the A/D conversion circuit 220 including the comparison circuit 209a, and the portion 203b of the supply line SL2 of the A/D conversion circuit 220 including the comparison circuit 209b. For example, the portion 204c of the supply line SL3 of the A/D conversion circuit 220 including the comparison circuit 209c is arranged between the portion 204b of the supply line SL2 of the A/D conversion circuit 220 including the comparison circuit 209b, and the portion 203c of the supply line SL3 of the A/D conversion circuit 220 including the comparison circuit 209c. That is, in the adjacent A/D conversion circuits 220, the portion 203 of the supply line SL of one A/D conversion circuit 220, or the portion 204 of the supply line SL of the other A/D conversion circuit 220 is arranged between the portion 204 of the supply line SL of one A/D conversion circuit 220, and the portion 203 of the supply line SL of the other A/D conversion circuit 220.

Generally, in circuit arrangements in the photoelectric conversion device 1, wiring patterns having the same function are formed in an equivalent shape with an equivalent impedance. That is, the impedances of the respective portions 203 of the supply lines SL can be equivalent, and those of the respective portions 204 can be equivalent. In contrast, the impedances of the portions 203 and 204 can have different values. When wiring patterns having different impedances are close to each other, potential variations readily affect the high-impedance wiring pattern from the low-impedance wiring pattern.

To prevent this, the parasitic capacitance between the portion 204 of the supply line SL that extends from the comparison circuit 209, and the portion 203 of the supply line SL that connects the portion 204 and the selection circuit 201 is reduced between the adjacent A/D conversion circuits 220 by the above-described arrangement of the supply lines SL. A crosstalk when different ramp signals are supplied to the comparison circuits 209 is suppressed between the adjacent A/D conversion circuits 220, thereby suppressing a change of the slope of the ramp signal. As a result, the photoelectric conversion device 1 in which the A/D conversion gain is kept uniform within an image and degradation of the quality of an obtained image is suppressed can be obtained.

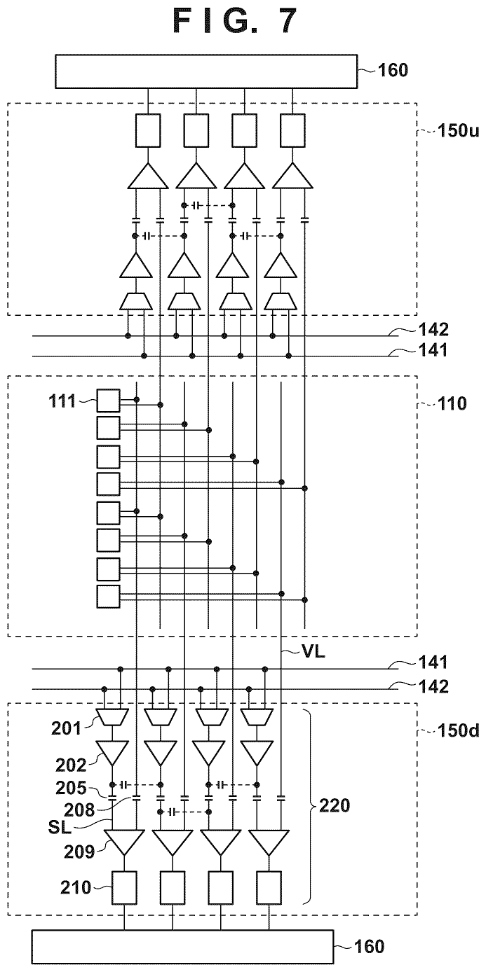

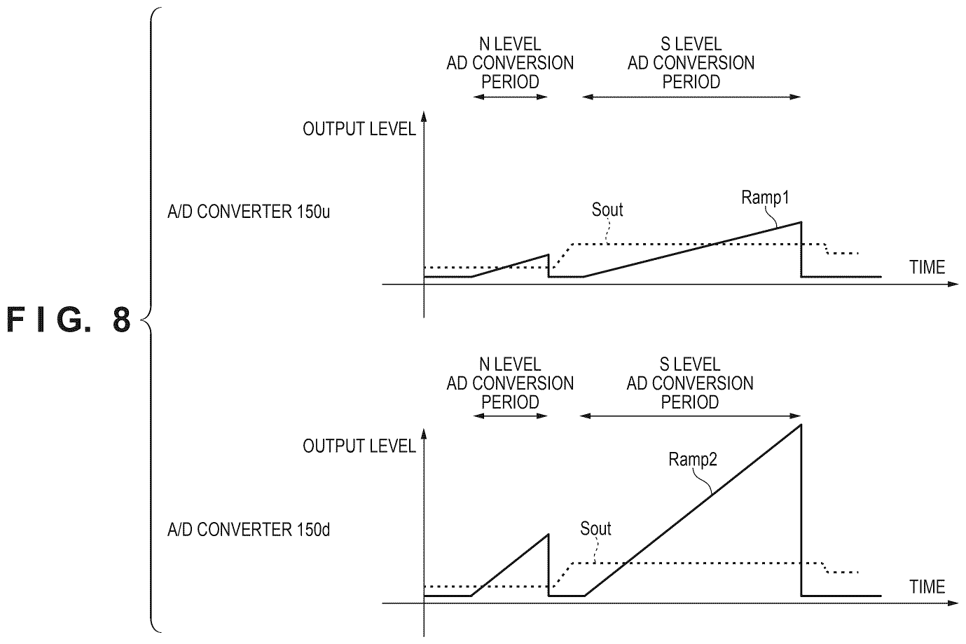

Next, the second embodiment of the present disclosure will be explained with reference to FIGS. 7 and 8. FIG. 7 is a circuit diagram showing a modification of a pixel circuit 110 and an A/D converter 150 shown in FIG. 2 in a photoelectric conversion device 1. Similar to the arrangement shown in FIG. 2, A/D converters 150u and 150d are provided on two sides of the pixel circuit 110. The arrangement of the A/D converters 150u and 150d may be similar to the arrangement shown in FIG. 2. The arrangement shown in FIG. 7 is different from the arrangement shown in FIG. 2 in the layout of signal output lines VL that connect pixels 111 and comparison circuits 209 arranged in respective A/D conversion circuits 220 of the A/D converter 150. More specifically, pixel signals from the respective pixels 111 arranged in the pixel circuit 110 can be output to both the A/D converters 150u and 150d via the signal output lines VL. The remaining arrangement may be similar to the arrangement in the above-described embodiment. For example, portions 203 and 204 of supply lines SL that connect selection circuits 201 and the comparison circuits 209 may have the above-mentioned symmetrical arrangement in a region 212.

The photoelectric conversion device 1 having the arrangement shown in FIG. 7 according to the embodiment may operate in the following driving mode, in addition to the above-described driving mode in which different ramp signals can be supplied to the adjacent A/D conversion circuits 220 in accordance with the levels of pixel signals. In the A/D converter 150u, the selection circuit 201 selects, from a plurality of ramp signal lines 141 and 142, for example, the ramp signal line 142 for supplying a ramp signal Ramp1, and the ramp signal Ramp1 is supplied to the comparison circuit 209. In this case, in the A/D converter 150d, the selection circuit 201 selects, from the ramp signal lines 141 and 142, the ramp signal line 141 for supplying a ramp signal Ramp2 different from that of the ramp signal line 142 for supplying the ramp signal Ramp1. As a result, a driving mode is set such that the ramp signal Ramp2 is supplied to the comparison circuit 209 of the A/D converter 150d. That is, in this driving mode, while the ramp signal Ramp1 (or Ramp2) is supplied to the comparison circuit 209 of a given A/D conversion circuit 220, the ramp signal Ramp1 (or Ramp2) is supplied to the comparison circuit 209 in the A/D conversion circuit 220 adjacent to the given A/D conversion circuit 220 in the A/D converters 150u and 150d. In other words, in this driving mode, while the ramp signal Ramp1 (or Ramp2) is supplied to the comparison circuit 209 of a given A/D conversion circuit 220, the ramp signal Ramp2 (or Ramp1) is not supplied to the comparison circuit 209 in the A/D conversion circuit 220 adjacent to the given A/D conversion circuit 220. This driving mode can be used to, for example, widen the dynamic range of a pixel signal by converting a pixel signal output from one pixel 111 at different A/D conversion gains and compositing the converted signals of the different A/D conversion gains. The photoelectric conversion device 1 may be configured to have the driving mode explained in the above-described first embodiment and the driving mode in the second embodiment, and switch the driving mode.

FIG. 8 is a timing chart showing the operation timings of the A/D converters 150u and 150d of the photoelectric conversion device 1 having the arrangement shown in FIG. 7. In the timing chart shown in FIG. 8, the selection circuit 201 in the A/D converter 150u selects the ramp signal line 142 to which the ramp signal Ramp1 is supplied. The selection circuit 201 in the A/D converter 150d selects the ramp signal line 141 to which the ramp signal Ramp2 is supplied. Hence, a voltage corresponding to the ramp signal Ramp1 is supplied as an input voltage VRAMP to the comparison circuit 209 arranged in the A/D converter 150u, and a voltage corresponding to the ramp signal Ramp2 is supplied as the input voltage VRAMP to the comparison circuit 209 arranged in the A/D converter 150d. By such an operation, ramp signals of the same slope are supplied to the adjacent A/D conversion circuit 220. That is, an unintentional change of the slope of the ramp signal arising from the above-described parasitic capacitance is suppressed.

The operation shown in FIG. 8 represents an example in which the ramp signal Ramp1 is supplied in the A/D converter 150u and the ramp signal Ramp2 is supplied in the A/D converter 150d. However, it suffices to supply ramp signals of the same slope to the A/D converters 150u and 150d. That is, for example, it is also possible to supply the ramp signal Ramp2 in the A/D converter 150u and the ramp signal Ramp1 in the A/D converter 150d.

In the driving mode according to the second embodiment described with reference to FIGS. 7 and 8, a ramp signal input when paying attention to one comparison circuit 209 is fixed to one ramp signal regardless of the level of a pixel signal. Thus, the operation (level determination period) of determining the level of a pixel signal in the first embodiment described with reference to FIG. 4B can be omitted. A pixel signal is simultaneously read out from the same pixel 111 to the A/D converters 150u and 150d, and the A/D converters 150u and 150d perform A/D conversion at different A/D conversion gains. As described above, two signals obtained by converting one pixel signal at different A/D conversion gains are composited by a subsequent signal processing circuit 170, an image processing LSI 2, or the like, thereby implementing a wide dynamic range of an obtained image and the like. In the A/D converters 150u and 150d, the same ramp signal is supplied to the adjacent A/D conversion circuits 220. Therefore, the photoelectric conversion device 1 in which a change of the slope of the ramp signal is suppressed, the A/D conversion gain is kept uniform within an image, and degradation of the quality of an obtained image is suppressed can be obtained.

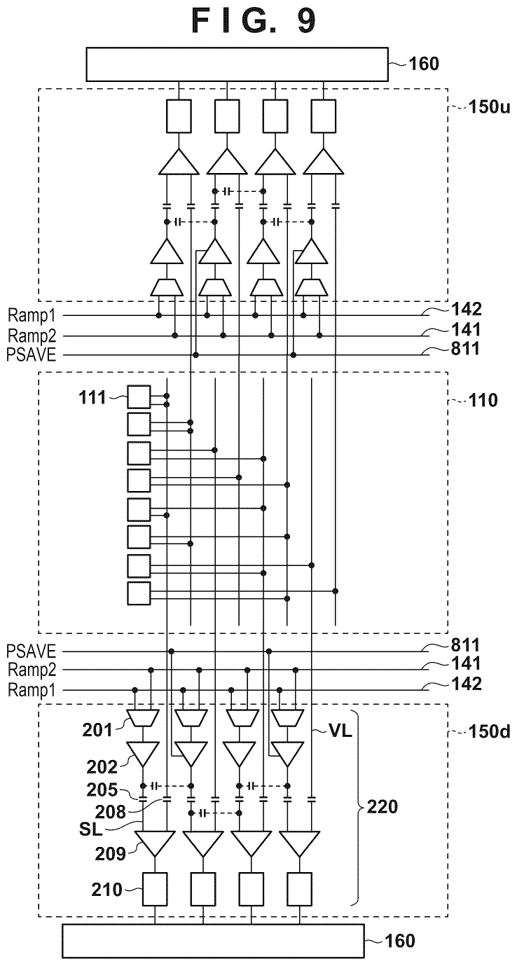

Next, the third embodiment of the present disclosure will be explained with reference to FIG. 9. FIG. 9 is a circuit diagram showing a modification of a pixel circuit 110 and an A/D converter 150 shown in FIGS. 2 and 7 in a photoelectric conversion device 1. Similar to the arrangements shown in FIGS. 2 and 7, A/D converters 150 u and 150 d are provided on two sides (top and bottom) of the pixel circuit 110.

In the arrangement shown in FIG. 9, the photoelectric conversion device 1 has a driving mode in which, while a predetermined ramp signal is supplied to a comparison circuit 209 in a given A/D conversion circuit 220 arranged in the A/D converter 150, a predetermined voltage is supplied to the comparison circuit 209 in an A/D conversion circuit 220 adjacent to the given A/D conversion circuit 220. The photoelectric conversion device 1 may be configured to have the driving modes in the above-described first and second embodiments and the driving mode in the third embodiment, switch between respective driving modes, and operate. An arrangement for implementing the driving mode according to the third embodiment will be explained.

As shown in FIG. 9, a stop signal PSAVE is input from a controller circuit 300 to buffer circuits 202 of the A/D converters 150u and 150d via stop signal lines 811. Upon receiving the stop signal PSAVE (for example, high level), the buffer circuits 202 stop the operation, and the output voltage is fixed to a predetermined voltage, for example, ground level. That is, some buffer circuits 202 function as even a circuit for stopping supply of a ramp signal from a selection circuit 201 to the comparison circuit 209. The output voltage of the buffer circuit 202 of the A/D conversion circuit 220 is fixed to a predetermined voltage using the stop signal PSAVE, thereby stopping supply of a ramp signal to the comparison circuit 209 in the A/D conversion circuit 220.

In each of the A/D converters 150u and 150d, the stop signal PSAVE can be supplied to the buffer circuit 202 of, for example, every second A/D conversion circuit 220 out of the plurality of A/D conversion circuits 220 arranged in correspondence with one pixel column. When the photoelectric conversion device 1 having the arrangement as shown in FIG. 9 operates in the driving mode in which the level of a pixel signal is determined in the above-described way and a ramp signal corresponding to the level of the pixel signal can be supplied, high level is input as the stop signal PSAVE. In response to this, the output voltage of the buffer circuit 202 connected to the stop signal line 811 is fixed to, for example, ground level. Pixels 111 include pixels that output pixel signals to only the A/D conversion circuits 220 to which the stop signal PSAVE is not supplied, and pixels that output pixel signals to the A/D conversion circuits 220 to which the stop signal PSAVE is not supplied and the A/D conversion circuits 220 to which the stop signal PSAVE is supplied. A/D conversion is performed using only the A/D conversion circuits 220 to which the stop signal PSAVE is not supplied. In other words, the driving mode according to the third embodiment is a driving mode in which A/D conversion is performed while thinning out the A/D conversion circuits 220.

As described above, the buffer circuit 202 is arranged at a portion 203 of a supply line SL. In the wiring layout shown in FIGS. 6A and 6B, for example, portions 203b and 203d of supply lines SL2 and SL4 are fixed to ground level. Thus, portions 204b and 204d of the supply lines SL2 and SL4 are also fixed to ground level. Even when different ramp signals are supplied to supply lines SL1 and SL3, a plurality of wiring patterns fixed to ground level including shield lines 230 are arranged between the supply lines SL1 and SL3. This suppresses an unintentional change of the slope of the ramp signal by capacitive coupling of the supply lines SL connected to the different A/D conversion circuits 220, as described above. As a result, the photoelectric conversion device 1 in which the A/D conversion gain is kept uniform within an image and degradation of the quality of an obtained image is suppressed can be obtained.

The circuit arrangements shown in FIGS. 2, 7, and 9 can be properly combined and used. That is, the photoelectric conversion device 1 may have a circuit arrangement in which it can operate in the three types of driving modes described above in the embodiments. For example, one photoelectric conversion device 1 may have at least two driving modes out of the above-described driving modes so that the driving modes can be appropriately switched and used by a user operation or the like. For example, the photoelectric conversion device 1 generally operates in the driving mode explained in the first embodiment. When the user selects a mode in which the dynamic range is widened, the photoelectric conversion device 1 operates in the driving mode explained in the second embodiment. When a mode in which higher-precision A/D conversion needs to be performed for improvement of the image quality, the photoelectric conversion device 1 operates in the driving mode explained in the third embodiment. This can implement the user-friendly photoelectric conversion device 1 in which characteristics are improved, such as improvement of the image quality by suppressing a crosstalk in A/D conversion, and widening of the dynamic range.

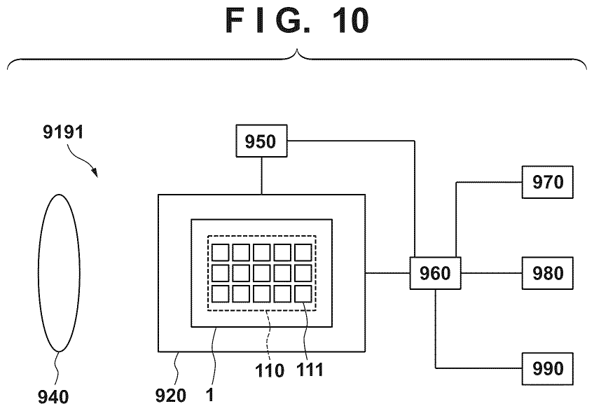

An application example of the photoelectric conversion device 1 according to the embodiment will be explained with reference to FIG. 10. FIG. 10 is a schematic view of an apparatus 9191 including the photoelectric conversion device 1. As shown in FIG. 10, the photoelectric conversion device 1 is housed in a package 920. The package 920 can include a base to which the photoelectric conversion device 1 is fixed, and a lid such as glass facing the photoelectric conversion device 1. The package 920 can further include joint members such as bonding wires and bumps that connect terminals provided on the base and pads provided on the photoelectric conversion device 1.

The apparatus 9191 can include at least one of an optical device 940, a control device 950, a processing device 960, a display device 970, a storage device 980, and a mechanical device 990. The optical device 940 is implemented by, for example, a lens, a shutter, and a mirror. The control device 950 controls the photoelectric conversion device 1. The control device 950 is, for example, a semiconductor device such as an ASIC.

The processing device 960 processes a signal output from the photoelectric conversion device 1. The processing device 960 is a semiconductor device such as a CPU or an ASIC for forming an analog front end (AFE) or a digital front end (DFE). The display device 970 is an EL display device or a liquid crystal display device that displays information (image) obtained by the photoelectric conversion device 1. The storage device 980 is a magnetic device or a semiconductor device that stores the information (image) obtained by the photoelectric conversion device 1. The storage device 980 is a volatile memory such as an SRAM or a DRAM, or a nonvolatile memory such as a flash memory or a hard disk drive.

The mechanical device 990 includes a moving or propulsion unit such as a motor or an engine. In the apparatus 9191, the signal output from the photoelectric conversion device 1 is displayed on the display device 970 or transmitted to an external device by a communication device (not shown) included in the apparatus 9191. Hence, the apparatus 9191 may further include the storage device 980 and the processing device 960 in addition to the memory circuits and arithmetic circuits included in the photoelectric conversion device 1. The mechanical device 990 may be controlled based on the signal output from the photoelectric conversion device 1.

In addition, the apparatus 9191 is suitable for an electronic apparatus such as an information terminal (for example, a smartphone or a wearable terminal) which has an image capturing function or a camera (for example, an interchangeable lens camera, a compact camera, a video camera, or a monitoring camera). The mechanical device 990 in the camera can drive the components of the optical device 940 in order to perform zooming, an in-focus operation, and a shutter operation. Alternatively, the mechanical device 990 in the camera can move the photoelectric conversion device 1 in order to perform an anti-vibration operation.

Furthermore, the apparatus 9191 can also be applied to an onboard camera mounted in a transportation apparatus such as a vehicle, a ship, an airplane, or an industrial robot. The mechanical device 990 in the transportation apparatus can be used as a moving device. The apparatus 9191 as the transportation apparatus is suitable for a device that transports the photoelectric conversion device 1 or a device that uses an image capturing function to assist and/or automate driving (steering). The processing device 960 for assisting and/or automating driving (steering) can perform, based on the information obtained by the photoelectric conversion device 1, processing for operating the mechanical device 990 as a moving device. The apparatus 9191 incorporating the photoelectric conversion device 1 can be widely applied to an apparatus using object recognition such as an intelligent transport system (ITS), in addition to the transportation apparatus. Alternatively, the apparatus 9191 may be a medical apparatus such as an endoscope, a measurement apparatus such as a distance measurement sensor, an analysis device such as an electron microscope, or an office apparatus such as a copy machine.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2024-072927, filed Apr. 26, 2024, which is hereby incorporated by reference herein in its entirety.

What is claimed is:

1. A photoelectric conversion device comprising: a pixel circuit in which a plurality of pixels are arranged to constitute a plurality of rows and a plurality of columns; a plurality of ramp signal lines to which ramp signals of different slopes are supplied; and an A/D converter in which a plurality of A/D conversion circuits including a first A/D conversion circuit and a second A/D conversion circuit that are adjacent to each other are arranged in correspondence with one column,
wherein each of the plurality of A/D conversion circuits includes a selection circuit configured to select a ramp signal line from the plurality of ramp signal lines to select a ramp signal used for A/D conversion, a comparison circuit configured to compare a ramp signal selected by the selection circuit with a pixel signal from the pixel, and a supply line configured to supply the ramp signal from the selection circuit to the comparison circuit,
the supply line includes a first portion extending from the comparison circuit, and a second portion connecting the first portion and the selection circuit, and
a wiring region in which the supply line is arranged includes, between the first portion of the first A/D conversion circuit and the second portion of the second A/D conversion circuit, a region where one of the second portion of the first A/D conversion circuit and the first portion of the second A/D conversion circuit is arranged.

2. The device according to claim 1, wherein in the region, the first portion and second portion of the first A/D conversion circuit and the first portion and second portion of the second A/D conversion circuit are arranged parallel on an identical wiring layer.

3. The device according to claim 1, wherein the supply line of each A/D conversion circuit is configured to supply the ramp signal from the selection circuit to the comparison circuit by capacitive coupling between the first portion and the second portion in the region.

4. The device according to claim 1, wherein in the region, a shield line is arranged between the first portion and second portion of the first A/D conversion circuit and the first portion and second portion of the second A/D conversion circuit.

5. The device according to claim 1, wherein the photoelectric conversion device has a driving mode in which the selection circuit selects, from the plurality of ramp signal lines in accordance with a level of the pixel signal, a ramp signal line for supplying the ramp signal used for A/D conversion.

6. The device according to claim 1, wherein the photoelectric conversion device has one of a driving mode in which, while the selection circuit selects, from the plurality of ramp signal lines, a ramp signal line for supplying a first ramp signal and the first ramp signal is supplied to the comparison circuit in the first A/D conversion circuit, the first ramp signal is supplied to the comparison circuit in the second A/D conversion circuit, and a driving mode in which a predetermined voltage is supplied.

7. A photoelectric conversion device comprising: a pixel circuit in which a plurality of pixels are arranged to constitute a plurality of rows and a plurality of columns; a plurality of ramp signal lines to which ramp signals of different slopes are supplied; and an A/D converter in which a plurality of A/D conversion circuits including a first A/D conversion circuit and a second A/D conversion circuit that are adjacent to each other are arranged in correspondence with one column,
wherein each of the plurality of A/D conversion circuits includes a selection circuit configured to select a ramp signal line from the plurality of ramp signal lines to select a ramp signal used for A/D conversion, a comparison circuit configured to compare a ramp signal selected by the selection circuit with a pixel signal from the pixel, and a supply line configured to supply the ramp signal from the selection circuit to the comparison circuit,
the supply line includes a first portion extending from the comparison circuit, and a second portion connecting the first portion and the selection circuit,
a wiring region in which the supply line is arranged includes a region where the first portion and second portion of the first A/D conversion circuit and the first portion and second portion of the second A/D conversion circuit are arranged parallel on an identical wiring layer, and
the photoelectric conversion device has at least one of a driving mode in which, while the selection circuit selects, from the plurality of ramp signal lines, a ramp signal line for supplying a first ramp signal and the first ramp signal is supplied to the comparison circuit in the first A/D conversion circuit, the first ramp signal is supplied to the comparison circuit in the second A/D conversion circuit, and a driving mode in which a predetermined voltage is supplied to the comparison circuit.

8. The device according to claim 7, wherein while the first ramp signal is supplied to the comparison circuit in the first A/D conversion circuit, a ramp signal different from the first ramp signal is not supplied to the selection circuit in the second A/D conversion circuit.

9. The device according to claim 7, wherein the A/D converter includes a first A/D converter and a second A/D converter,
the pixel circuit is arranged between the first A/D converter and the second A/D converter, and
the photoelectric conversion device has a driving mode in which in the first A/D converter, the selection circuit selects, from the plurality of ramp signal lines, the ramp signal line for supplying the first ramp signal, and in the second A/D converter, the selection circuit selects, from the plurality of ramp signal lines, a ramp signal line for supplying a second ramp signal that is different from the ramp signal line for supplying the first ramp signal.

10. The device according to claim 9, wherein each of the plurality of pixels is configured to output a pixel signal to both the first A/D converter and the second A/D converter.

11. The device according to claim 7, wherein a circuit configured to stop supply of the ramp signal from the selection circuit to the comparison circuit is arranged on the supply line of the second A/D conversion circuit.

12. The device according to claim 11, wherein a buffer circuit is arranged on the supply line, and
supply of the ramp signal is stopped by fixing an output voltage of the buffer circuit of the second A/D conversion circuit to the predetermined voltage.

13. The device according to claim 12, wherein the predetermined voltage includes ground level.

14. The device according to claim 12, wherein the buffer circuit is arranged at the second portion of the supply line.

15. The device according to claim 11, wherein the plurality of pixels include a pixel configured to output a pixel signal to the first A/D conversion circuit, and a pixel configured to output a pixel signal to the first A/D conversion circuit and the second A/D conversion circuit.

16. An apparatus comprising:
a photoelectric conversion device defined in claim 1; and
a processing device configured to process a signal output from the photoelectric conversion device.
